(19) United States
(12) Patent Application Publication
(10) Pub. No.: US 2023/0090001 A1
(43) Pub. Date: Mar. 23, 2023

(54) BATTERY DIAGNOSTIC SYSTEM

(71) Applicant: DENSO CORPORATION, Kariya-city (JP)

(72) Inventors: Yuji YAMAGAMI, Kariya-city (JP); Shuhei YOSHIDA, Kariya-city (JP); Hisashi UMEMOTO, Kariya-city (JP)

(21) Appl. No.: 18/070,233

(22) Filed: Nov. 28, 2022

Related U.S. Application Data
(63) Continuation of application No. PCT/JP2021/021694, filed on Jun. 8, 2021.

(30) Foreign Application Priority Data
Jun. 26, 2020 (JP) 2020-110536

(51) Int. Cl. G01R 31/389; G01R 31/36; G01R 31/392; G01R 31/3842

(52) U.S. Cl. CPC G01R 31/389; G01R 31/3648; G01R 31/392; G01R 31/3842

(57) ABSTRACT

A battery diagnostic system includes a superimposed current applying unit, a current value acquiring unit, a voltage value acquiring unit, an impedance calculating unit, and a diagnostic unit. The superimposed current applying unit configured to apply a superimposed current formed by superimposing a plurality of frequency components to a battery. The current value acquiring unit acquires the current value of the superimposed current applied to the battery. The voltage value acquiring unit acquires a battery voltage of the battery to which the superimposed current is applied. The impedance calculating unit calculates impedance for each of a plurality of frequency components using discrete Fourier transform from the superimposed current and the battery voltage. The diagnostic unit diagnoses the battery based on the impedance.

### CROSS REFERENCE TO RELATED APPLICATIONS

This application is a continuation application of International Patent Application No. PCT/JP2021/021694 filed on Jun. 8, 2021, which designated the U.S. and based on and claims the benefits of priority of Japanese Patent Application No. 2020-110536 filed on Jun. 26, 2020. The entire disclosure of all of the above applications is incorporated herein by reference.

### TECHNICAL FIELD

The present disclosure relates to a battery diagnostic system.

### BACKGROUND

Batteries have come to be widely used in recent years, but since a state of the battery changes and deteriorates as it is used, it is necessary to diagnose a deterioration state of the battery.

The present disclosure is to provide a battery diagnostic system capable of increasing the diagnostic speed with a simple configuration.

One aspect of the battery diagnostic system of the present disclosure includes,

a superimposed current applying unit configured to apply to a battery a superimposed current obtained by superimposing a plurality of frequency components,

a current value acquiring unit configured to acquire a current value of the superimposed current applied to the battery,

a voltage value acquiring unit configured to acquire a battery voltage of the battery to which the superimposed current is applied,

an impedance calculating unit configured to calculate impedance for each of a plurality of frequency components using a discrete Fourier transform from the superimposed current and a voltage of the battery, and

a diagnostic unit configured to diagnose the battery based on the impedance.

### BRIEF DESCRIPTION OF DRAWINGS

The above and other objects, features and advantages of the present disclosure will become more apparent from the following detailed description taken in conjunction with the accompanying drawings.

In the drawings:

FIG. 1 is a block diagram showing a configuration of a battery diagnostic system according to a first embodiment 1;

FIG. 2A is a conceptual diagram showing an example of superimposed current in the first embodiment;

FIG. 2B is a conceptual diagram showing an example of superimposed current in the first embodiment;

FIG. 2C is a conceptual diagram showing an example of superimposed current in the first embodiment;

FIG. 2D is a conceptual diagram showing an example of superimposed current in the first embodiment;

FIG. 3 is a conceptual diagram showing a circuit configuration of the battery diagnostic system in the first embodiment;

FIG. 4 is a conceptual diagram showing multiple sinusoidal current in the first embodiment;

FIG. 5 is a flowchart showing diagnostic steps in the battery diagnostic system in the first embodiment;

FIG. 6A is a conceptual diagram showing a superimposed current in the battery diagnostic system in the first embodiment;

FIG. 6B is a conceptual diagram showing FFT conversion results in the battery diagnostic system in the first embodiment;

FIG. 7 is a conceptual diagram showing impedance calculation results in the battery diagnostic system in the first embodiment;

FIG. 8 is a conceptual diagram showing measurement accuracy in the battery diagnostic system in the first embodiment;

FIG. 9A is a conceptual diagram showing an example of superimposed currents in the first embodiment;

FIG. 9B is a conceptual diagram showing an example of superimposed currents in the first embodiment;

FIG. 10 is a conceptual diagram showing a circuit configuration of a battery diagnostic system according to a modified first embodiment;

FIG. 11 is a conceptual diagram showing a circuit configuration of the battery diagnostic system in a second embodiment;

FIG. 12 is a conceptual diagram showing a circuit configuration of the battery diagnostic system in a third embodiment; and

FIG. 13 is a conceptual diagram showing a circuit configuration of the battery diagnostic system in a modified second embodiment.

### DETAILED DESCRIPTION

Batteries have come to be widely used in recent years, but since a state of the battery changes and deteriorates as it is used, it is necessary to diagnose the deterioration state of the battery. In an assumed example, a configuration for diagnosing a deterioration state by acquiring frequency characteristics of impedance of a secondary battery is known as a battery diagnostic system. In such a configuration, a switching element is provided between a drive circuit for driving an electric load and a secondary battery for supplying power to the drive circuit. Then, by turning on/off the switching element at a desired frequency, an impedance frequency characteristic of the secondary battery is obtained from a current value and a voltage value of the secondary battery detected when the DC voltage between the secondary battery and the drive circuit is converted at a desired switching frequency, and an internal resistance of the secondary battery is calculated. This makes it possible to acquire the frequency characteristic of the impedance of the secondary battery without using an oscillator for giving an AC signal to the secondary battery.

In the configuration disclosed above, at least one cycle of measurement is required for each frequency, and multiple frequencies cannot be measured simultaneously. Therefore, as the number of frequencies to be measured increases, the measurement of each frequency requires at least the sum of the time for one cycle of each frequency, and the diagnostic speed becomes low. Therefore, if it is desired to perform feedback control based on the diagnostic result while the battery is being charged and discharged, for example, while the battery installed in the vehicle is in use, such as while the vehicle is running, the diagnostic speed may not keep up in the configuration described above.

The present disclosure is to provide a battery diagnostic system capable of increasing the diagnostic speed with a simple configuration.

One aspect of the battery diagnostic system of the present disclosure includes,

a superimposed current applying unit configured to apply to a battery a superimposed current obtained by superimposing a plurality of frequency components,

a current value acquiring unit configured to acquire a current value of the superimposed current applied to the battery,

a voltage value acquiring unit configured to acquire a battery voltage of the battery to which the superimposed current is applied,

an impedance calculating unit configured to calculate impedance for each of a plurality of frequency components using a discrete Fourier transform from the superimposed current and a voltage of the battery, and

a diagnostic unit configured to diagnose the battery based on the impedance.

In the battery diagnostic system, superimposed current in which a plurality of frequency components are superimposed are applied to the battery, and the battery state is diagnosed by calculating the impedance for each frequency by Fourier transform from the detected battery voltage and superimposed current. As a result, since the battery voltage when currents of multiple frequencies are applied can be obtained collectively, it is possible to increase the diagnostic speed compared to the case where the battery voltage is obtained by sequentially applying currents of a plurality of frequencies. Moreover, since it is not necessary to use an oscillator or the like when applying the superimposed current to the battery, the configuration can be simplified.

As described above, according to the above-described embodiments, it is possible to provide the battery diagnostic system capable of increasing the diagnostic speed with a simple configuration.

### First Embodiment

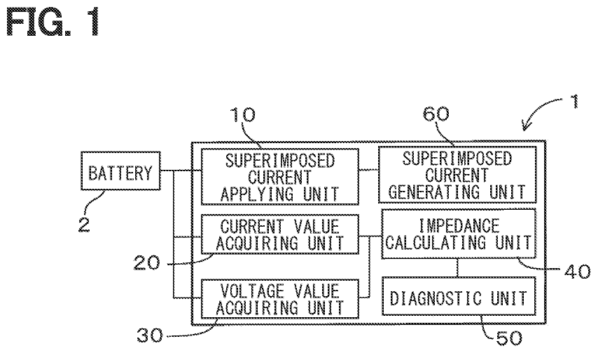

An embodiment of the battery diagnostic system will be described with reference to FIGS. 1 to 9.

As shown in FIG. 1, a battery diagnostic system 1 of the present embodiment includes a superimposed current applying unit 10, a current value acquiring unit 20, a voltage value acquiring unit 30, an impedance calculating unit 40, and a diagnostic unit 50.

The superimposed current applying unit 10 applies to a battery 2 a superimposed current obtained by superimposing a plurality of frequency components.

The current value acquiring unit 20 acquires the current value of the superimposed current applied to the battery 2.

The voltage value acquiring unit 30 acquires a battery voltage of the battery to which the superimposed current is applied.

The impedance calculating unit 40 calculates impedance for each of a plurality of frequency components using discrete Fourier transform from the superimposed current and the battery voltage.

The diagnostic unit 50 diagnoses the battery 2 based on the impedance.

Hereinafter, the battery diagnostic system 1 of the present embodiment will be described in detail below.

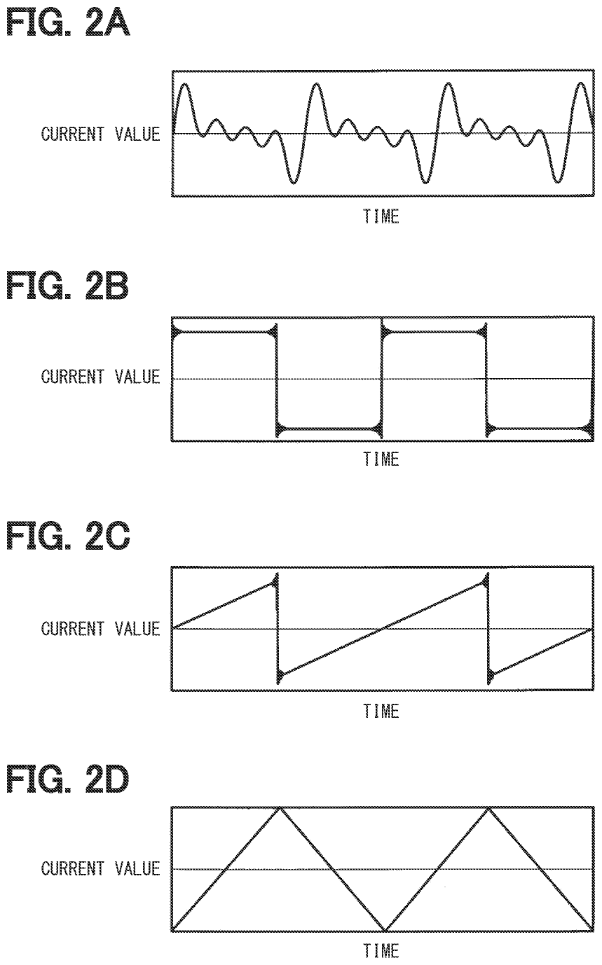

The superimposed current applying unit 10 shown in FIG. 1 applies a superimposed current to the battery 2. A plurality of frequency components are superimposed on the superimposed current. As the superimposed current may be, for example, a multiple sinusoidal wave obtained by superimposing a plurality of limiting waves as shown in FIG. 2A, a rectangular wave as shown in FIG. 2B, a sawtooth wave as shown in FIG. 2C, or a triangular wave as shown in FIG. 2D. Among them, it is preferable to employ a multiple sinusoidal wave as the superimposed current. In harmonics with respect to the fundamental frequency as superimposed frequencies of rectangular waves, sawtooth waves and triangular waves, the current value is significantly reduced as the order increases. However, since each current value of the superimposed frequencies in the multiple sinusoidal wave is not reduced, high measurement accuracy can be maintained. In the multiple sinusoidal wave, the frequency to be superimposed is not particularly limited and can be set as appropriate. The superimposed current applying unit 10 can be configured by a BMU (battery management unit) connected to the battery, or a vehicle EPU (engine control unit) when the battery is mounted on a vehicle. Also, the superimposed current applying unit 10 can be configured in a predetermined diagnostic device provided in a service station, or realized by a program stored on a cloud using a data transmission/reception device (not shown).

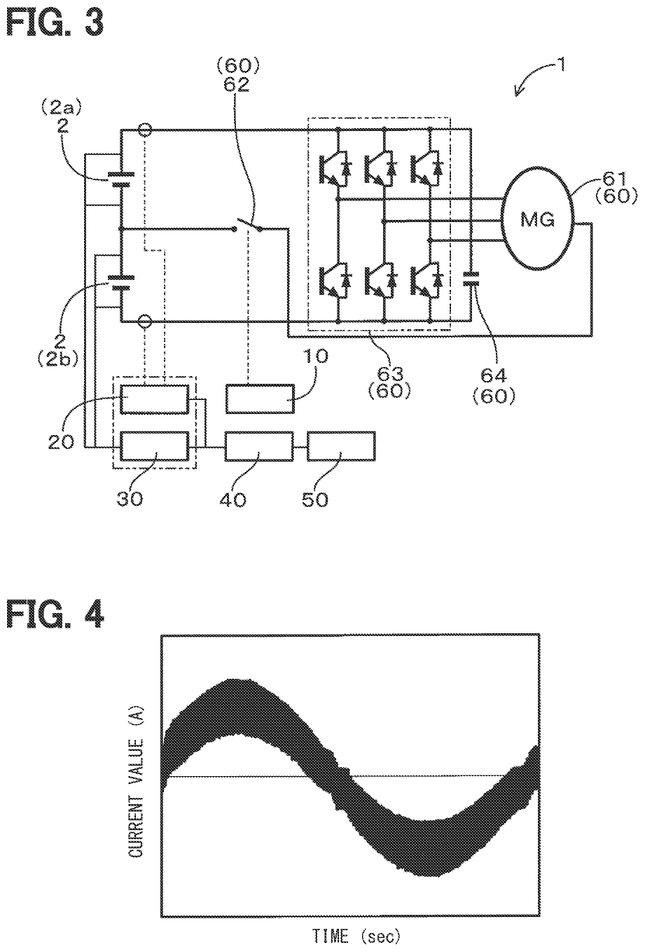

The type of battery 2 shown in FIG. 1 is not particularly limited. In the first embodiment, the battery 2 is a secondary battery and constitutes a power source mounted on an electric vehicle or a hybrid vehicle. As shown in FIG. 3, as the battery 2, a first battery 2a and a second battery 2b are connected in series. Although both the batteries 2a and 2b constitute a battery module having a plurality of cells, they are not limited to this configuration, and may be a single battery having a single cell.

The current value acquiring unit 20 shown in FIG. 1 detects the current value of the superimposed current applied to the battery 2. In the first embodiment, as shown in FIG. 3, the current value is detected by a current sensor provided on a power line connected to the battery 2. For example, the current value acquiring unit 20 can detect the superimposed current as indicated by diagonal lines in FIG. 4. The voltage value acquiring unit 30 shown in FIG. 1 detects the battery voltage when the superimposed current is applied to the battery 2. In the first embodiment, as shown in FIG. 3, the voltage value acquiring unit 30 is configured to detect the battery voltages of the batteries 2a and 2b using voltage sensors capable of detecting the battery voltages of the batteries 2a and 2b. In the first embodiment, the current value acquiring unit 20 and the voltage value acquiring unit 30 are loggers manufactured by Keyence, model number NR600.

The impedance calculating unit 40 shown in FIG. 1 calculates the impedance for each of a plurality of frequency components using a discrete Fourier transform from the superimposed current detected by current value acquiring unit 20 and the battery voltage detected by voltage value acquiring unit 30. A fast discrete Fourier transform (FFT) can be employed as the discrete Fourier transform. The diagnostic unit 50 shown in FIG. 1 diagnoses battery 2 based on the impedance for each frequency component acquired by impedance calculating unit 40. The impedance calculating unit 40 and the diagnostic unit 50 can be configured by a vehicle EPU when a BMU and a battery are mounted on the vehicle. Also, the impedance calculating unit 40 and the diagnostic unit 50 can be configured in a predetermined diagnostic device provided in a service station, or realized by a program stored on a cloud using a data transmission/reception device (not shown). In the first embodiment, MATLAB (registered trademark) is used as the impedance calculating unit 40.

A superimposed current is generated by the superimposed current generating unit 60 shown in FIG. 1. The configuration of the superimposed current generating unit is not limited, and for example, can be a power conversion device or a configuration including a boost converter, a switch, and a smoothing capacitor or a capacitor including a battery. Thereby, for example, a superimposed current of a maximum of about 200 A can be generated. In the first embodiment, as shown in FIG. 3, the superimposed current generating unit 60 is composed of a power conversion device 63, a switch 62, and a smoothing capacitor 64, which constitute an inverter in the electric vehicle. A neutral point of the MG (Motor Generator) as a load connected to the power conversion device 63 and a neutral point of the battery 2 are connected through the switch 62. Thereby, the power conversion device 63 and the load 61 can be operated as a step-up/step-down chopper, and ripple current (reactive power) can be exchanged between the batteries 2a and 2b without a capacitor. Then, the superimposed current applying unit 10 controls the on/off of the switch 62 to generate the superimposed current and applies it to the batteries 2a and 2b. That is, since the ripple current is exchanged between the batteries 2a and 2b, one of the two batteries 2a and 2b functions as a capacitor with respect to the other. According to this configuration, it is possible to supply a ripple current as a superimposed current into the battery 2 without passing through the capacitor, so that the size of the capacitor can be reduced. Also, the ripple frequency can be lowered, and noise during temperature rise can be reduced.

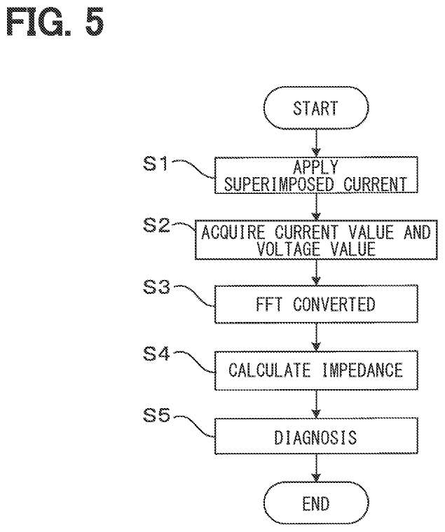

Next, a control flow of the battery diagnostic system 1 of the first embodiment will be described with reference to FIG. 5.

First, in step S1 shown in FIG. 5, the superimposed current applying unit 10 applies the superimposed current generated in the superimposed current generating unit 60 to the batteries 2a and 2b. In the first embodiment, the batteries 2a and 2b each have four cells, and the total capacity is 25 Ah. In the first embodiment, the superimposed current is applied to the batteries 2a and 2b at 50 Hz intervals between 50 and 300 Hz at 10 A command current.

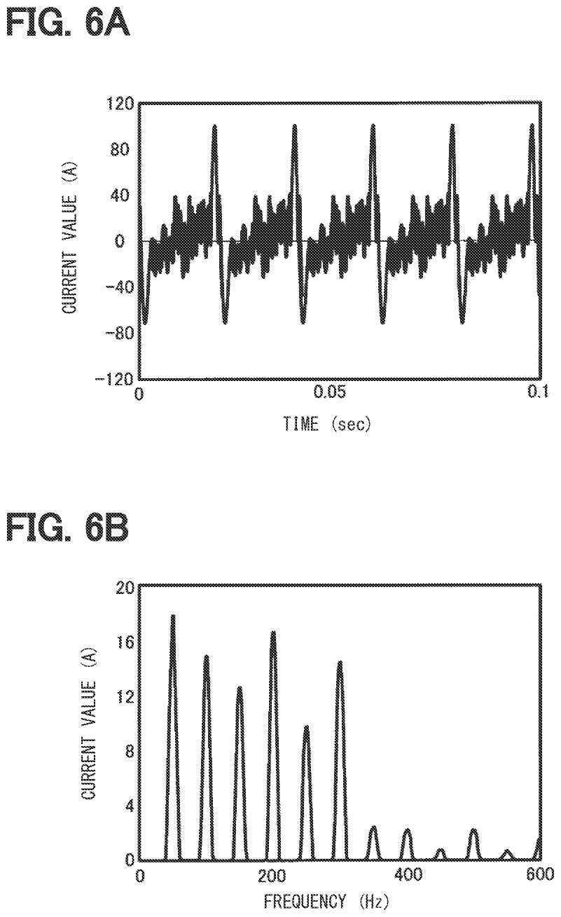

After that, in step S2 shown in FIG. 5, the current value of the superimposed current shown in FIG. 6A applied to the batteries 2a and 2b is acquired by the current value acquiring unit 20. Further, in addition to acquiring the current value, the voltage value acquiring unit 30 acquires the battery voltages of the batteries 2a and 2b. The acquired current value and voltage value are averaged or AD-converted as appropriate using a low-pass filter.

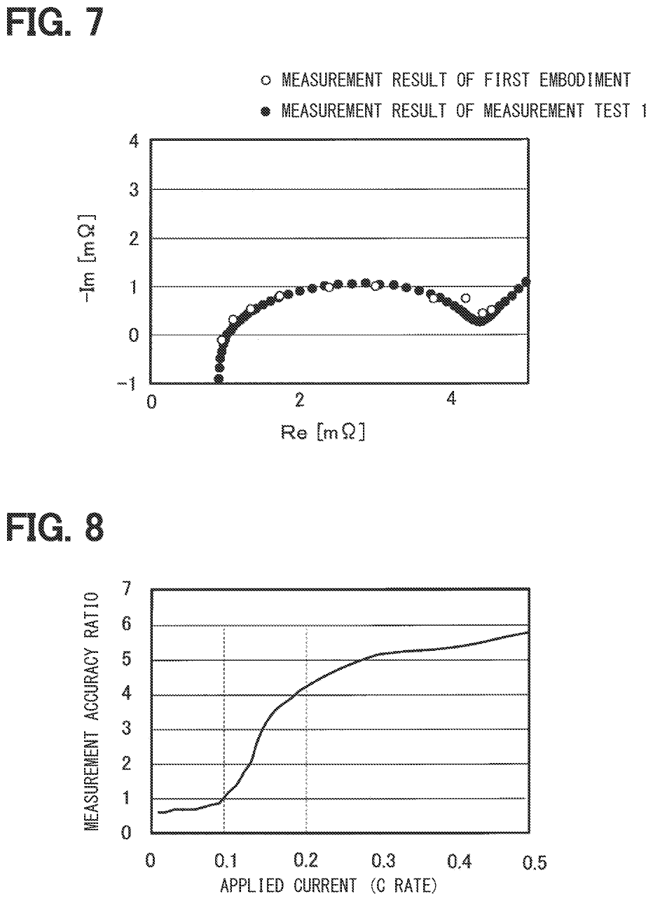

Next, in step S3 shown in FIG. 5, the current value is FFT-converted by the impedance calculating unit 40. In the present embodiment, as shown in FIG. 6B, the current value of the superimposed current is separated into frequency components. Although not shown, voltage values are also separated into frequency components. Then, the current value and the voltage value are obtained as complex vectors I(ω) and V(ω), respectively, and based on the following equations 1 and 2, a complex impedance plane plot (Cole-Cole plot) is created, as shown in FIG. 7.

Z=|I(ω)|/|V(ω)|, and cos θ=|V/|I∥V| (Equation 1)

Re=Z cos θ, and Im=Z sin θ (Equation 2)

Thereafter, in step S4 shown in FIG. 5, the impedance calculating unit 40 calculates the impedance from the Cole-Cole plot. Then, in step S5 in FIG. 5, the diagnostic unit 50 diagnoses the batteries 2a and 2b based on the impedance calculation result, and the control flow ends.

Next, a verification of impedance calculation results of the battery diagnostic system 1 of the first embodiment will be described. As measurement test 1, the impedance of battery 2 was measured using a frequency response analyzer, and the measurement results are plotted in FIG. 7. As shown in FIG. 7, this verification shows that the impedance calculation result according to the first embodiment has measurement accuracy substantially equal to the measurement result of the measurement test 1.

Next, a comparison test of the calculation speed of the impedance calculation result of the battery diagnostic system 1 of the first embodiment will be described.

The comparative embodiment has a circuit that applies current to the battery using a FET (field effect transistor) through a path different from the power line through which a large current flows and is connected to the power conversion device 63 in the battery diagnostic system 1 of the first embodiment shown in FIG. 2, and the comparative embodiment is a conventional configuration in which an MCU (micro control unit) performs complex vector conversion of current and voltage values by Fourier transform to calculate impedance. The applied current in the comparative embodiment is 0.1 A. On the other hand, in the first embodiment, as in the control flow described above, a 10 A command current is superimposed at intervals of 50 Hz between 50 and 300 Hz. Then, the time required from the start of current application to the calculation of the impedance is compared. As a result of the test, the measurement time in the first embodiment was 41 when the measurement time in the comparative embodiment was 100. According to the test result, it is shown that the impedance calculation speed of the battery diagnostic system 1 according to the first embodiment is sufficiently faster than that of the comparative embodiment.

Next, verification of measurement accuracy of the battery diagnostic system 1 of the first embodiment will be described.

A measurement variation σA when a current of 0.1 A is applied to the configuration of the above-described comparative embodiment, and a measurement variation σB when the applied current is changed in the range of 0 to 0.5C rate in the battery diagnostic system 1 of the first embodiment are obtained. The ratio σA/σB between the measurement variations σA and σB was calculated as the measurement accuracy ratio, and the correspondence relationship with the applied current is shown in FIG. 8.

As shown in FIG. 8, the measurement accuracy ratio was 1 or more when the applied current C rate was 0.1 or more, and the measurement accuracy ratio was 4 or more when the applied current C rate was 0.2 or more. Therefore, from the verification results, if the superimposed current contains a frequency component with a C rate of 0.1 C or higher, where C is the capacity of the battery to be diagnosed, the measurement accuracy equal to or higher than the conventional configuration can be ensured. Furthermore, if a frequency component with a C rate of 0.2C or higher is included, sufficiently higher measurement accuracy than the conventional configuration can be obtained.

Next, the effects of the battery diagnostic system 1 of the first embodiment will be described in detail.

In the battery diagnostic system 1 of the first embodiment, superimposed current in which a plurality of frequency components are superimposed are applied to the batteries 2a and 2b, and the battery state is diagnosed by calculating the impedance for each frequency by Fourier transform from the detected battery voltage and superimposed current. As a result, since the battery voltage when currents of multiple frequencies are applied can be obtained collectively, it is possible to increase the diagnostic speed compared to the case where the battery voltage is obtained by sequentially applying currents of a plurality of frequencies. Moreover, since it is not necessary to use an oscillator or the like when applying the superimposed current to the battery, the configuration can be simplified.

The waveform of the superimposed current is at least one of a triangular wave, a rectangular wave, a sawtooth wave, and a multiple sinusoidal wave. This makes it possible to easily generate the superimposed current in which currents having a plurality of frequencies are superimposed. And, in the first embodiment, the waveform of the superimposed current is the multiple sinusoidal wave. As a result, each superimposed component can also maintain the current value, thereby preventing deterioration in measurement accuracy.

In the first embodiment, the superimposed current includes a frequency component having a C rate of 0.1 C or more, where C is the capacity of the batteries 2a and 2b to be diagnosed. Thereby, a large current is applied to the batteries 2a and 2b, and the measurement accuracy can be improved. Therefore, it is possible to achieve both an improvement in diagnostic speed and an improvement in measurement accuracy.

Further, in the first embodiment, the superimposed current generating unit 60 has the power conversion device 63, the switch 62, and batteries 2a and 2b as capacitors, and is configured to generate the above-described superimposed current. As a result, in a case where the batteries 2a and 2b are mounted as a power source of an electric vehicle or the like, the superimposed current generating unit 60 can be configured onboard using the power conversion device 63 of the electric vehicle or the like and the power line connected thereto, and be configured to be suitable for diagnosing the in-vehicle battery.

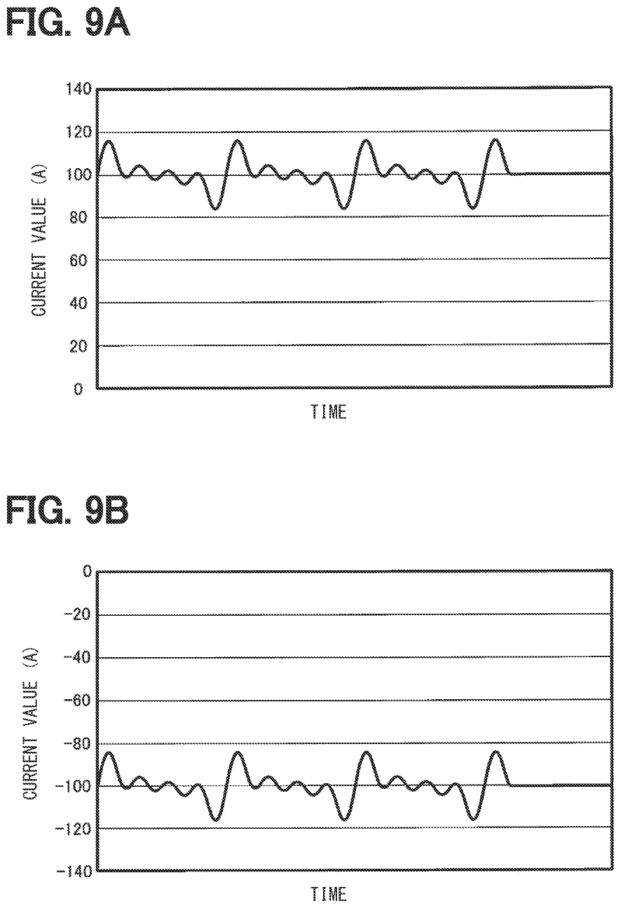

Also, the superimposed current applying unit 10 may apply the superimposed current to the batteries 2a and 2b during charging or discharging of the batteries 2a and 2b. As the superimposed current applied during charging of the battery, for example, a current having a waveform shown in FIG. 9A can be used. In the battery 2 mounted on the vehicle, the superimposed current shown in FIG. 9A may be applied to the battery 2 in order to calculate the impedance during power supply during regeneration or running. As the superimposed current applied during discharge of the battery, for example, a current having a waveform shown in FIG. 9B can be used. In addition, in the battery 2 mounted on the vehicle, the superimposed current shown in FIG. 9B may be applied to the battery 2 for impedance calculation during running or when power is supplied as a battery system. According to the above configuration, since the diagnostic speed is increased as described above, the diagnostic result can be obtained during charging or discharging of the battery, and it is possible to contribute to implementation of feedback control.

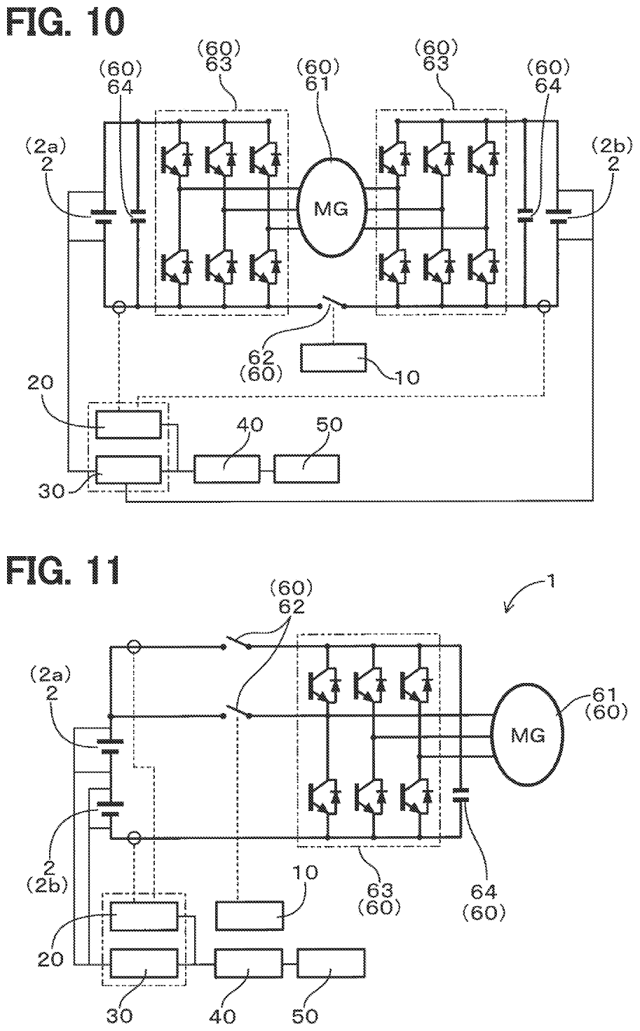

Two superimposed current generating units 60 may be provided as in a modified embodiment 1 shown in FIG. 10. Also in the modified embodiment 1, the ripple current is exchanged between the batteries 2a and 2b, and the same effect as in the first embodiment is achieved.

As described above, according to the above-described embodiments, it is possible to provide the battery diagnostic system 1 capable of increasing the diagnostic speed with a simple configuration.

### Second Embodiment

In the battery diagnostic system 1 of a second embodiment, as shown in FIG. 11, the superimposed current generating unit 60 is configured to exchange ripple current between the battery 2 and a smoothing capacitor 64 as a capacitor. Other components are equivalent to those in the first embodiment and given the same reference signs as those in the first embodiment, and description thereof is omitted. The second embodiment also provides operation and effects similar to those of the first embodiment.

### Third Embodiment

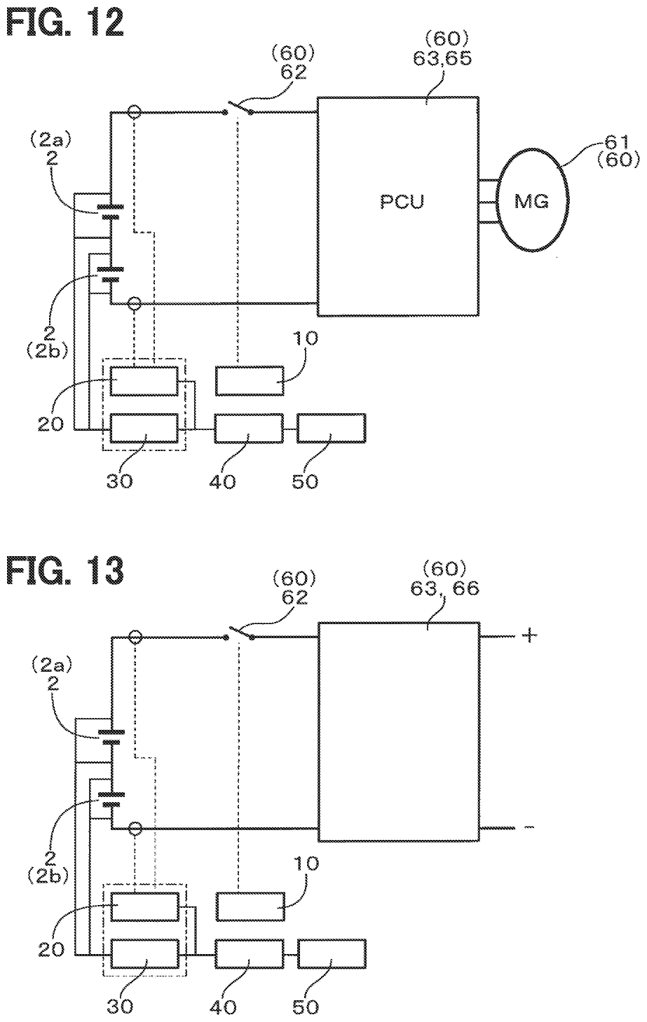

The battery diagnostic system 1 of a third embodiment is a battery diagnostic system used for diagnosing a battery 2 mounted on a hybrid vehicle. As shown in FIG. 12, the battery diagnostic device has a PCU (power control unit), and the PCU includes a power conversion device 63 and a boost converter 65 as a superimposed current generating unit 60. Other components are equivalent to those in the first embodiment and given the same reference signs as those in the first embodiment, and description thereof is omitted. The third embodiment also provides operation and effects similar to those of the first embodiment.

As in a modified embodiment 2 shown in FIG. 13, an external charger 66 that also functions as the power conversion device 63 may be used as the superimposed current generating unit 60. Also in the modified embodiment 2, the same effects as those of the third embodiment can be obtained.

The present disclosure is not limited to the respective embodiments described above, and various modifications may be adopted within the scope of the present disclosure without departing from the spirit of the disclosure.

Although the present disclosure has been described in accordance with the embodiments, it is understood that the present disclosure is not limited to such embodiments or structures. The present disclosure includes various modifications and variations within the scope of equivalents. In addition, while various combinations and configurations, which are preferred, other combinations and configurations including further only a single element, more or less, are also within the spirit and scope of the present disclosure.

The unit and method described in the present disclosure may be implemented by a special purpose computer which is configured with a memory and a processor programmed to execute one or more particular functions embodied in computer programs of the memory. Alternatively, the control calculation unit described in the present disclosure and the method thereof may be realized by a dedicated computer configured as a processor with one or more dedicated hardware logic circuits. Alternatively, the control calculation unit and method described in the present disclosure may be realized by one or more dedicated computer, which is configured as a combination of a processor and a memory, which are programmed to perform one or more functions, and a processor which is configured with one or more hardware logic circuits. The computer programs may be stored, as instructions to be executed by a computer, in a tangible non-transitory computer-readable medium.

What is claimed is:

1. A battery diagnostic system, comprising:
a superimposed current applying unit configured to apply a superimposed current formed by superimposing a plurality of frequency components to a battery;
a current value acquiring unit configured to acquire a current value of the superimposed current applied to the battery;
a voltage value acquiring unit configured to acquire a battery voltage of the battery to which the superimposed current is applied;
an impedance calculating unit configured to calculate impedance for each of a plurality of frequency components using a discrete Fourier transform from the superimposed current and a voltage of the battery; and
a diagnostic unit configured to diagnose the battery based on the impedance.

2. The battery diagnostic system according to claim 1, wherein
a waveform of the superimposed current is at least one of a triangular wave, a rectangular wave, a sawtooth wave, and a multiple sinusoidal wave.

3. The battery diagnostic system according to claim 1, wherein
a waveform of the superimposed current is a multiple sinusoidal wave.

4. The battery diagnostic system according to claim 1, wherein
the superimposed current includes a frequency component having a C rate of 0.1 C or higher, where C is a capacity of the battery to be diagnosed.

5. The battery diagnostic system according to claim 1, further comprising,
a superimposed current generating unit including a power conversion device or a boost converter, a switch and a smoothing capacitor or a capacitor having a battery, and configured to generate the superimposed current.

6. The battery diagnostic system according to claim 1, wherein
the superimposed current applying unit applies the superimposed current to the battery during charging or discharging of the battery.

7. A battery diagnostic system, comprising:
a processor and a memory that stores instructions configured to, when executed by the processor, cause the processor to
apply a superimposed current formed by superimposing a plurality of frequency components to a battery;
acquire a current value of the superimposed current applied to the battery;
acquire a battery voltage of the battery to which the superimposed current is applied;
calculate impedance for each of a plurality of frequency components using a discrete Fourier transform from the superimposed current and a voltage of the battery; and
diagnose the battery based on the impedance.

8. The battery diagnostic system according to claim 7, wherein
a waveform of the superimposed current is at least one of a triangular wave, a rectangular wave, a sawtooth wave, and a multiple sinusoidal wave.

9. The battery diagnostic system according to claim 7, wherein
a waveform of the superimposed current is a multiple sinusoidal wave.

10. A battery diagnostic method, comprising:
applying a superimposed current formed by superimposing a plurality of frequency components to a battery;
acquiring a current value of the superimposed current applied to the battery;
acquiring a battery voltage of the battery to which the superimposed current is applied;
calculating impedance for each of a plurality of frequency components using a discrete Fourier transform from the superimposed current and a voltage of the battery; and
diagnosing the battery based on the impedance.

11. The battery diagnostic method according to claim 10, wherein
a waveform of the superimposed current is at least one of a triangular wave, a rectangular wave, a sawtooth wave, and a multiple sinusoidal wave.

12. The battery diagnostic method according to claim 10, wherein
a waveform of the superimposed current is a multiple sinusoidal wave.
